(19) United States
(12) Patent Application Publication
(10) Pub. No.: US 2006/0108594 A1
(43) Pub. Date: May 25, 2006

(54) LED device and method for manufacturing the same

(76) Inventors: Kazuyuki Iwasaki, Tokyo (JP); Fusao Suzuki, Tokyo (JP)

Correspondence Address: CERMAK & KENEALY, LLP, 515 EAST BRADDOCK RD SUITE B, Alexandria, VA, 22314, US

(21) Appl. No.: 11/269,669

(22) Filed: Nov. 9, 2005

(30) Foreign Application Priority Data
Nov. 11, 2004 (JP) 2004-327878

(51) Int. Cl. H01L 33/00

(52) U.S. Cl. 257/98

(57) ABSTRACT

An LED device can include LED chips mounted with high density and encapsulated with a resin. The device may not be substantially affected by fluctuations in thermal stress generated in the encapsulating resin and can have reduced fluctuations in characteristics such as output power and a color tone and can have a high level of reliability which can be maintained over a long period of time. The LED device can be manufactured by a method that includes mounting LED chips with high density on a metal stem having conductive-material-made leads that extend from the metal stem, welding a lens holder having a lens temporarily fixed thereto by a silicone resin to the stem so as to enclose the LED chips, and encapsulating the LED chips and bonding wires by injecting a silicone resin serving as an encapsulating resin having translucency and flexibility into a space defined by the stem, the holder, and the lens.

This application claims the priority benefit under 35 U.S.C. §l 119 of Japanese Patent Application No. 2004-327878 filed on Nov. 11, 2004, which is hereby incorporated in its entirety by reference.

### BACKGROUND OF THE INVENTION

1. Field of the Invention

The invention relates to an LED device emitting high power and/or multicolor light by mounting at least one LED chip and to a method for manufacturing the same.

2. Description of the Related Art

A light emitting diode (LED) is a light emitting element made of semiconductor materials and is formed by joining a p-type semiconductor and an n-type semiconductor. The light emission principle of an LED is that a bias voltage is applied in the forward direction to convert electrical energy to light energy at the junction (an active layer). The peak light emission wavelength of an LED depends on the semiconductor materials, but falls within the wavelength range of ultra violet rays via visible rays to infrared rays, and the light emission spectrum has steep characteristics.

Generally, a light emission element (an LED chip) of an LED device has a hexahedral shape (a dice-like shape) having a side length of about 0.5 mm. The light emission element is small and emits a small amount of light, and thus the optical properties thereof are close to those of a point source of light. Therefore, if an LED device is designed and produced by use of the LED chip having such properties as a light source, certain techniques are employed. For example, the ratio of the amount of light emitted from the LED chip to the amount of light generated in the active layer of the LED chip (external quantum efficiency) is increased, and the light emission intensity on the optical axis of the LED device is increased by gathering the light emitted from the LED chip and radiating it to the outside in one direction.

Thus, if an LED device is required to emit high intensity light and the amount of light emitted from one LED chip does not meet the requirement specification, a plurality of LED chips having the same light source color can be mounted to increase the light intensity. Moreover, if an LED device is required to emit multicolor light, LED chips having different light source colors can be mounted to implement an LED device emitting a predetermined color tone obtained by additive color mixture in which the light emitted from the respective LED chips are appropriately combined.

When electric power is supplied to an LED chip to emit light, not all of the electrical energy supplied to the LED chip is converted to light energy. A part of the electrical energy supplied to the LED chip is not converted to light energy, and most of the unconverted electrical energy is converted to thermal energy to increase the temperature of the LED chip itself.

In addition, as the temperature of the LED chip increases, the efficiency for converting electrical energy to light energy decreases. Thus, the ratio of thermal energy converted from the electrical energy increases to cause the amount of light emitted from the LED chip to further decrease.

If the amount of the electric energy supplied to the LED chip is increased in order to recover the light emission amount reduced by the self heating of the LED chip, the self heating of the LED chip increases, and the efficiency for converting to light energy is reduced, thereby resulting in a vicious circle. Thus, the temperature of the LED chip further increases, and the increased amount of the emitted light is not commensurate with the increased amount of the electrical energy.

If a plurality of the LED chips having such characteristics are mounted with high density and simultaneously turned on, the temperature increase of the LED chips as a whole is larger than that when a single LED chip or loosely mounted LED chips are turned on. This is due to the interaction of the self heating between the LED chips, resulting in the reduction of the light emission efficiency with respect to the supplied electrical energy.

Thus, when a plurality of LED chips are mounted with high density in a sealed package, a substrate on which the LED chips are mounted is formed of a high thermal conductivity material, including metals such as copper and aluminum and ceramics, and the temperature increase in the package is suppressed by dissipating the self heat of each LED chip to the outside (the atmosphere) via the substrate.

Further, in order to radiate the small amount of light emitted from each of the LED chips to the outside with high efficiency and predetermined light distribution, a condenser having a convex shape is provided in front of the LED chip in the light emission direction thereof. In this case, depending on the working environment of the LED device, particularly if the LED device is used outdoors, the condenser receives short wavelength light such as blue light and ultra violet light included in sunlight and thus receives light having a wavelength shorter than or equal to that of blue light. The condenser also receives short wavelength light emitted from the light sources themselves such as from a blue LED chip and an ultra violet LED chip.

If the condenser is formed of an epoxy resin generally employed as an encapsulating resin for an LED chip, the light transmissivity of the epoxy resin decreases to cause the light extracting efficiency to deteriorate. This is because the epoxy resin has a property that the color thereof is changed from no color tone (transparent) to yellow when the resin is irradiated with short wavelength light. Accordingly, the intensity of light of the LED device is reduced. Further, if LED chips having different light source colors are mounted, the radiated light occasionally exhibits poor color rendering properties since the color tone obtained by appropriately combining the light beams emitted from the respective LED chips through additive color mixture is changed.

In order to avoid such problems, the condenser may be formed of a glass material for preventing the deterioration of the optical properties of the condenser from being accelerated by short wavelength light (light having a wavelength shorter than or equal to that of blue light).

In view of the above problems, in manufacturing an LED device having a plurality of LED chips mounted with high density, a semiconductor laser diode device employing a package capable of addressing the above-mentioned problems has been proposed. (The problems are caused by the heat generated by the LED chips, the working environment where light having a wavelength shorter than or equal to that of blue light is present, the condenser provided for radiating a small amount of light emitted from each of the LED chips to the outside with high efficiency and predetermined light distribution properties, and the like.)

If the above package is looked at in detail, a package having the same configuration as that in the above package is found to be usable in the case where a plurality of LED chips are mounted with high density (see, for example, Japanese Patent Laid-Open Publication No. Hei 8-37339). The configuration of a conventional semiconductor laser diode device is shown in FIG. 1. In the semiconductor laser diode device, a supporting member 52 is integrally formed with a stem 51 having a plurality of leads 50 extending out therefrom, and a heat sink 54 having a semiconductor laser chip 53 mounted thereon is fixed to the supporting member 52. A cap 56 having a glass window 55 arranged around the optical axis of the semiconductor laser chip 53 is mounted on the stem 51 so as to enclose the supporting member 52, the heat sink 54, and the semiconductor laser chip 53.

As shown in FIG. 2, an attempt is made to produce another type of LED device having a configuration similar to that of the above-mentioned semiconductor laser diode device, except that a plurality of LED chips 60 are mounted with high density in place of the supporting body 52 provided on the stem 51, the heat sink 54, and the semiconductor laser diode 53. In addition, a convex shaped lens 57 is attached in place of the glass window attached to the cap 56.

In this case, in order to attach the heavy lens 57 to the cap 56, the lens 57 is bonded to the cap 56 by use of a hard and strong adhesive material 58 such as an epoxy adhesive agent or a glass hermetic seal.

In addition, the space defined by the stem 51, the lens 57, and the cap 56 is filled with a silicone resin 59 to encapsulate the LED chips 60 mounted on the stem 51 and bonding wires 61 within the resin.

However, if the LED chips mounted with high density in the silicone resin filled in the firmly sealed space are repeatedly turned on and off, a crack (a fracture) is occasionally generated inside the resin. Interfacial peeling also occasionally occurs between the resin and a component mounted on the interface.

When a glass lens is used as an example, the stresses generated in the resin are applied to the glass lens in a normal state shown in FIG. 3A, causing a flange portion to chip as shown in FIG. 3B or to fracture as shown in FIG. 3C.

Moreover, thermal stress simulations for inspecting the stress state in the resin reveals that the stresses in the resin are concentrated particularly on the inner surface of the cap. This may be caused by cure shrinkage stresses generated when the silicone resin that is filled in the firmly sealed space is cured in a furnace during a production process, or by stress fluctuations generated inside the resin during the process when the resin is heated by the heat generated by each LED chip, or when the resin is cooled.

### SUMMARY OF THE INVENTION

According to an aspect of the invention, a high power and high reliability LED device can be provided in which at least one LED chip is mounted in a sealed space and is encapsulated with a resin, and in which a lens is provided in front of the LED chip in the light emission direction. The LED device may not be substantially affected by stress fluctuations of the encapsulating resin generated during heating or cooling of the resin by the varying heat generated by the LED chip.

Another aspect of the invention is to provide an LED device having a stem with a plurality of leads made of a conductive material. At least one LED chip can be located adjacent the stem and capable of emitting light in a light emitting direction. A lens holder having a cylindrical shape and an opening can enclose the at least one LED chip. A lens can be positioned in front of the at least one LED chip in the light emission direction and attached to the lens holder with a first resin having flexibility and hermeticity values that are greater than flexibility and hermeticity values for either epoxy or acrylic resins, respectively. An encapsulating resin having flexibility and translucency can be filled into a space defined by the stem, the lens holder, and the lens, the space enclosing the at least one LED chip, so that the at least one LED chip is encapsulated with the encapsulating resin.

Another of the aspects of the invention is to provide an LED device. The LED device can include: a stem having a plurality of leads made of a conductive material and extending out therefrom; at least one LED chip mounted on the stem; a lens holder having a cylindrical shape and an opening enclosing the LED chip; a lens positioned in front of the LED chip in a light emission direction and attached to the lens holder with a resin having flexibility and hermeticity; and an encapsulating resin having flexibility and translucency and being filled into a space defined by the stem, the lens holder, and the lens. The space can enclose the LED chip so that the LED chip is encapsulated with the resin.

In the above LED device, the resin having flexibility and hermeticity may be a silicone resin.

The above LED device may have a plurality of the LED chips each having a light source color within a wavelength range from ultra violet rays to infrared rays; and the plurality of LED chips may be composed of LED chips having the same light source color or a combination of LED chips having different light source colors.

In the LED device, the stem can be made of a material exhibiting good heat dissipation effect and, for example, the stem can be made of a metal material.

Another aspect of the invention is a method for manufacturing an LED device that can include: locating at least one LED chip adjacent a stem that has a plurality of leads made of a conductive material; fixing a lens to a lens holder with a first resin having flexibility and hermeticity values that are greater than flexibility and hermeticity values for either epoxy or acrylic resins, respectively; fixing the lens holder to the stem so as to enclose the at least one LED chip; and filling a space defined by the stem, the lens holder, and the lens with an encapsulating resin having flexibility and translucency, the space enclosing the at least one LED chip so that the at least one LED chip is encapsulated with the encapsulating resin.

Another aspect of the invention is a method for manufacturing an LED device. The method can include: mounting at least one LED chip on a stem having a plurality of leads made of a conductive material and extending therefrom; fixing a lens to a lens holder with a resin having flexibility and hermeticity; fixing the lens holder to the stem so as to enclose the LED chip; and filling a space defined by the stem, the lens holder, and the lens with an encapsulating resin having flexibility and translucency, the space enclosing the LED chip, so that the LED chip is encapsulated with the resin.

In the above method for manufacturing an LED device, the resin having flexibility and hermeticity may be a silicone resin.

In the above method for manufacturing an LED device, the device may have a plurality of the LED chips each having a light source color within a wavelength range from ultra violet rays to infrared rays. The plurality of LED chips may be composed of LED chips having the same light source color or a combination of LED chips having different light source colors.

In the above method for manufacturing an LED device, the stem can be made of a material exhibiting good heat dissipation effect and, for example, can be made of a metal material.

An exemplary embodiment of an LED device made in accordance with principles of the invention can be formed by mounting at least one LED chip on a stem, attaching a lens holder having a lens fixed thereto by a resin having flexibility and hermeticity to the stem so as to enclose the LED chip, and resin-encapsulating the LED chip by injecting a resin having flexibility and translucency into a space defined by the stem, the lens holder, and the lens.

Therefore, the stresses generated during curing of the encapsulating resin and the fluctuations in thermal stresses in the encapsulating resin generated when the LED chip is turned on or off can be absorbed and relaxed by the resin which fixes the lens to the lens holder. Thus, cracks can be prevented from forming in the lens and the encapsulating resin. This provides an advantage that a high level of reliability of the LED device can be maintained over a long period of time.

### BRIEF DESCRIPTION OF THE DRAWINGS

These and other characteristics, features, and advantages of the invention will become clear from the following description with reference to the accompanying drawings, wherein:

FIG. 1 is a cross-sectional view illustrating a conventional power device;

FIG. 2 is a cross-sectional view illustrating another conventional LED device;

FIGS. 3A, 3B, and 3C are perspective views illustrating the state of a lens employed in an LED device, FIG. 3A showing a lens in a normal state, FIG. 3B showing a lens having a flange portion chipped by thermal stresses, and FIG. 3C showing a lens having a flange portion fractured by thermal stresses;

FIG. 4 is a top view illustrating an exemplary embodiment of an LED device made in accordance with principles of the invention;

FIG. 5 is a cross-sectional view taken along line A-A of FIG. 4; and

FIG. 6 is a schematic flowchart illustrating exemplary manufacturing processes in accordance with principles of the invention.

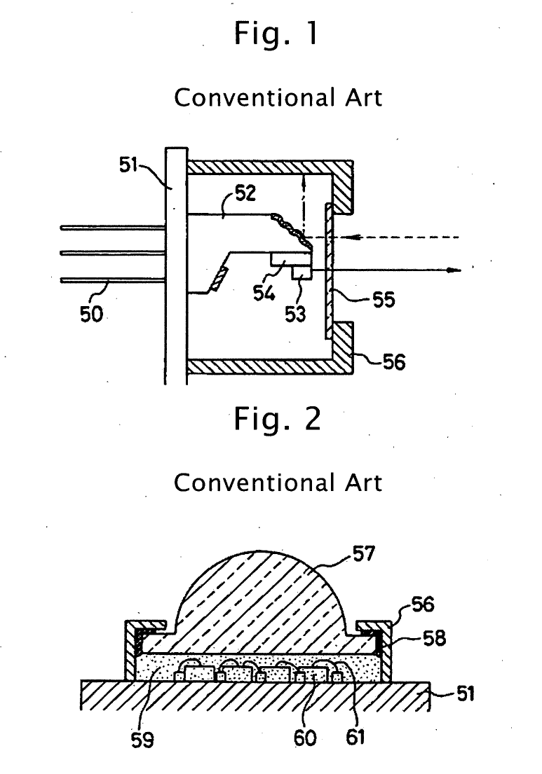

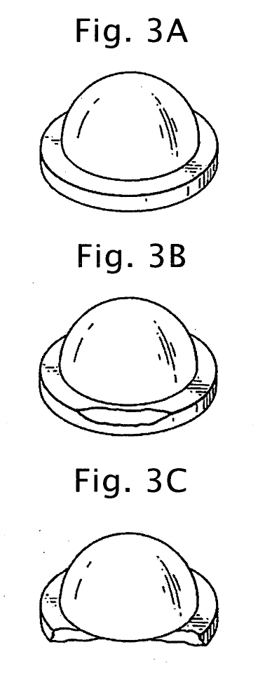

### DETAILED DESCRIPTION OF PREFERRED EMBODIMENTS

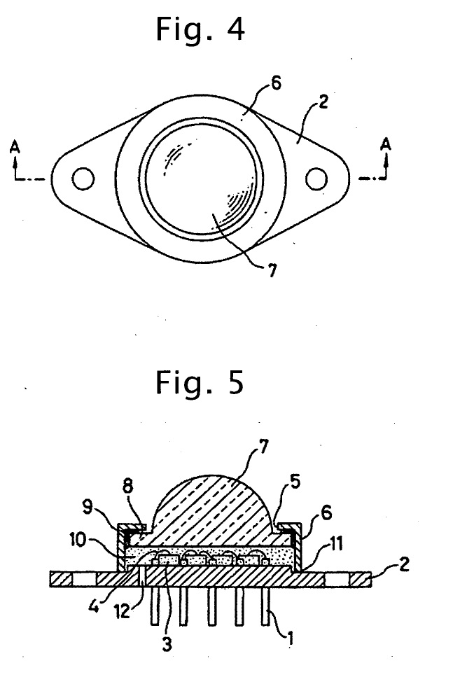

Exemplary embodiments of the invention will next be described in detail with reference to FIGS. 4 to 6. The same reference numerals will be used for the same or similar parts. The exemplary embodiment to be described hereinafter is an example of a structure made in accordance with principles of the invention, and various technical features are imposed thereon. However, the scope of the invention is not limited to this exemplary embodiment.

FIG. 4 is a top view illustrating an exemplary embodiment of an LED device made in accordance with principles of the invention, and FIG. 5 is a cross-sectional view taken along line A-A of FIG. 4. A plurality of leads 1 made of a conductive material can extend out from a stem 2, and an LED chip 3 (or a plurality of LED chips 3) can be mounted with high density on the stem 2 via a conductive adhesive material or other attachment structure or material. A lower electrode of each of the LED chips 3 can be electrically connected with the stem 2.

The stem 2 can be made of a material including metal materials, ceramics including an electric wiring, glass epoxy resins, and the like. A stem can be made of a metal material having high thermal conductivity and exhibiting good heat dissipation effect. For example, a metal such as copper or aluminum can be employed. In the embodiment shown in FIG. 4, the metal stem is formed of copper.

An upper electrode of each of the LED chips 3 can be connected to one end face of each of the leads 1 via a bonding wire 4 to establish electrical connection between the LED chips 3 and respective leads 1.

A cylindrical lens holder 6 having a window 5 formed as an opening can also be attached to the stem 2 so as to enclose the LED chips 3 as a whole. The lens holder 6 can be made of a metal material and be integrally formed with the stem 2 via a welded portion 11 such that the window 5 is aligned with the light emission direction of the LED chips 3. The lens holder 6 of this exemplary embodiment can be made of an Fe—Ni alloy.

A lens 7 having a spherical surface projecting toward the light emission direction of the LED chips 3 can be provided adjacent the window 5 of the lens holder 6. The lens 7 can be made of a glass and temporarily fixed to the window 5 by sealing the space between a flange portion 8 of the lens and the lens holder 6 with a temporary fixing resin 9 (such as a silicone resin) having flexibility and hermeticity values that are greater than respective values of flexibility and hermeticity for either epoxy or acrylic resins. It being understood that the epoxy or acrylic resins are those commonly used in the LED art for attachment of LED device components. The lens shape can be spherical, aspherical, etc., and is selected depending on the desired light distribution property, the distance between the LED chip and the lens surface, and the like.

The space enclosed by the stem 2, the lens 7, and the lens holder 6 can be filled with an encapsulating resin 10 such as a silicone resin having flexibility and translucency. Thus, the LED chip 3 and the bonding wires 4 can be resin-encapsulated. The encapsulating resin may have a hardness of from 10 to 100 as measured by JIS A type test (JIS K 6301), and more particularly can have a hardness of from 25 to 40 in view of improved and/or different operation characteristics.

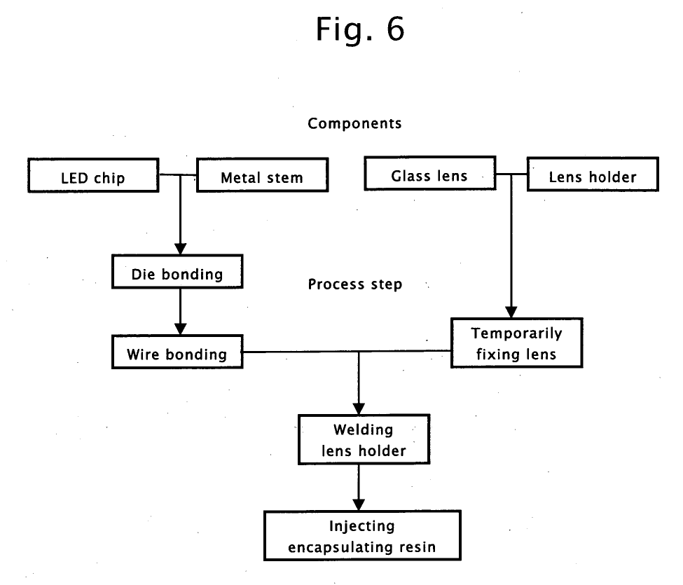

Next, an exemplary method for manufacturing the above LED device will be described with reference to the process flowchart of FIG. 6. First, a metal stem 2 having a plurality of leads 1 extending out therefrom is prepared. A plurality of LED chips 3 can be fixed to the metal stem 2 via a conductive adhesive material (a die bonding process) or via other known attachment processes or structures.

Subsequently, the upper electrode of each of the LED chips 3 can be connected to one end face of the corresponding lead 1 by the bonding wire 4 (a wire bonding process).

A lens holder 6 is prepared to have a cylindrical shape with openings on respective ends. A window 5 can be formed in the central portion of one opening by inwardly bending the edge of the lens holder 6. A glass lens 7 having a flange portion 8 can be inserted into the lens holder 6 from the opening opposite to the window 5 to allow the convex portion of the glass lens 7 to project from the window 5 of the lens holder 6 and to allow the flange portion 8 to abut the lens holder 6. In this state, the glass lens 7 can be temporarily fixed to the lens holder 6 by a temporary fixing resin 9 such as a silicone resin having flexibility and hermeticity (a lens temporary fixing process).

Subsequently, the lens holder 6 having the glass lens 7 temporarily fixed thereto can be arranged on the metal stem 2 so as to enclose the LED chips 3, and can be integrated with the metal stem 2 via a welded portion 11 (a lens holder welding process).

Finally, the space enclosed by the metal stem 2, the glass lens 7, and the lens holder 6 can be filled with an encapsulating resin 10 such as a silicone resin having flexibility and translucency. The encapsulating resin 10 can be injected into an encapsulating resin injection hole 12 provided in the metal stem 2 to thereby resin-encapsulate the LED chip 3 and the bonding wires 4 (an encapsulating resin injection process).

In the lens temporary fixing process, the temporary fixing resin 9 for fixing the glass lens 7 to the lens holder 6 should have an adequate adhesion strength to prevent the glass lens from falling off the lens holder upon welding the lens holder to the metal stem in the subsequent lens holder welding process. In this embodiment, a silicone resin which contains a rubber-based adhesive component can be employed as the temporary fixing resin 9.

Upon completion of the assembly, forces and impacts applied from the outside to the glass lens are absorbed and relaxed by the encapsulating resin. Therefore, also in this respect, it is sufficient to temporarily fix the glass lens with a strength that is enough to prevent it from falling off during the lens holder welding process.

In the above manufacturing processes, a characteristic of the operation efficiency can be simultaneously performing the die bonding process and the wire bonding process as well as the lens temporary fixing process. Furthermore, the obtained assemblies can be joined in the lens holder welding process and then sent to the encapsulating resin injection process.

Table 1 shows a relationship between a temporary fixing resin material for temporarily fixing the flange portion of the glass lens to the lens holder with respect to cracks that form in either the lens or the encapsulating resin.

TABLE 1
[Relationship between material for
temporary fixing resin and crack]

| | | Evaluation after curing | | | |
|---|---|---|---|---|---|
| | Brief | | Crack in | | Young's |
| | description | Crack | encapsu- | | modulus |
| Type | of resin | in lens | lating resin | Hardness | (GPa) |
| A | Two component | Yes | Yes | 80 (JIS-D) | 3.0 |
| | epoxy resin | | | | |
| B | Two component | No | No | 38 (JIS-A) | 0.00098 |
| | silicone resin | | | | |
| C | One component | No | No | 27 (JIS-A) | 0.0003 |
| | low hardness | | | | |
| | silicone resin | | | | |
| D | UV curable | Yes | Yes | 75 (JIS-D) | 0.098 |
| | acrylic resin | | | | |

If an epoxy-resin or an acrylic resin was employed for the temporary fixing resin, cracks were generated in both the glass lens and the encapsulating resin. On the other hand, if a silicone resin (one component type or two component type) was employed for the temporary fixing resin, cracks were generated in neither the glass lens nor the encapsulating resin. These results have demonstrated that the temporary fixing resin having flexibility absorbs thermal stresses to relax the effects of the stresses on the glass lens. Thus, a resin having a hardness of from 25 to 40 as measured by JIS A type test (JIS K 6301) and a Young's modulus of less than 0.001 GPa is suitable for the temporary fixing resin having flexibility.

As described above, in an exemplary embodiment of an LED device made in accordance with principles of the invention, the space in which at least one LED chip is mounted can be encapsulated with a flexible and translucent resin. The lens enclosing the above described space can be temporarily fixed to the lens holder by use of a resin having flexibility and hermeticity.

Therefore, if thermal stresses are generated in the encapsulating resin by heat generated during powering up the LED chip, the stresses can be absorbed and relaxed by the flexible resin temporarily fixing the lens, thereby preventing cracks from generating in the lens and the encapsulating resin.

If the LED chip is brought into a turned-off state from a turned-on state, the thermal stresses are typically decreased by the temperature decrease caused by turning off the LED chip. Also in this case, the resin which temporarily fixes the lens serves as a cushioning material for the stress fluctuations, thereby preventing cracks from generating.

In addition, in order to allow the small amount of light emitted from the LED chip to radiate to the outside with high efficiency and with a predetermined light distribution, the lens provided in front of the LED chip in the light emitting direction can be formed of glass. Therefore, depending on the working environment of the LED device, particularly if the LED device is used outdoors, the lens receives short wavelength light such as blue light and ultra violet light that are included in sunlight (the light having a wavelength shorter than or equal to that of blue light) and also receives short wavelength light emitted from the light sources themselves such as from a blue LED chip or an ultra violet LED chip. However, even in such a case, the optical properties may be hardly affected according to the configuration of the LED device described above.

Therefore, an LED device having a high level of reliability which can be maintained over a long period of time and having reduced fluctuations in characteristics such as output power and a color tone can be implemented.

Although the exemplary processes described above occur in a certain order, it should be understood that the order in which each of the processes occurs can be varied and changed without departing from the spirit and scope of the invention. In addition, it should be understood that although the lens holder 6 is depicted in the figures as a circular tube, the shape of the lens holder 6 can be varied in accordance with the application or desire of the manufacturer or consumer. For example, the lens holder 6 as viewed from above can be a square, triangular, polygonal, non-circular, non-symmetric, etc. cylindrical shape. It therefore follows that the lens 7 can also be variously shaped in order to fit within the corresponding lens holder 6.

While there has been described what are at present considered to be exemplary embodiments of the invention, it will be understood that various modifications may be made thereto, and it is intended that the appended claims cover all such modifications as fall within the true spirit and scope of the invention.

What is claimed is:

1. An LED device comprising:
a stem having a plurality of leads made of a conductive material;
at least one LED chip located adjacent the stem and capable of emitting light in a light emitting direction;
a lens holder having a cylindrical shape and an opening enclosing the at least one LED chip;
a lens positioned in front of the at least one LED chip in the light emission direction and attached to the lens holder with a first resin having flexibility and hermeticity values that are greater than flexibility and hermeticity values for either epoxy or acrylic resins, respectively; and
an encapsulating resin having flexibility and translucency and being filled into a space defined by the stem, the lens holder, and the lens, the space enclosing the at least one LED chip, so that the at least one LED chip is encapsulated with the encapsulating resin.

2. The LED device according to claim 1, wherein the first resin is a silicone resin.

3. The LED device according to claim 1, wherein:
the device has a plurality of the LED chips each having a light source color within a wavelength range from ultra violet rays to infrared rays; and
the plurality of LED chips are composed of LED chips having the same light source color or a combination of LED chips having different light source colors.

4. The LED device according to claim 2, wherein:
the device has a plurality of the LED chips each having a light source color within a wavelength range from ultra violet rays to infrared rays; and
the plurality of LED chips are composed of LED chips having the same light source color or a combination of LED chips having different light source colors.

5. The LED device according to claim 1, wherein the stem is made of a material exhibiting good heat dissipation effect.

6. The LED device according to claim 1, wherein the stem is made of a metal material.

7. A method for manufacturing an LED device comprising:
locating at least one LED chip adjacent a stem that has a plurality of leads made of a conductive material;
fixing a lens to a lens holder with a first resin having flexibility and hermeticity values that are greater than flexibility and hermeticity values for either epoxy or acrylic resins, respectively;
fixing the lens holder to the stem so as to enclose the at least one LED chip; and
filling a space defined by the stem, the lens holder, and the lens with an encapsulating resin having flexibility and translucency, the space enclosing the at least one LED chip so that the at least one LED chip is encapsulated with the encapsulating resin.

8. The method for manufacturing an LED device according to claim 7, wherein the first resin is a silicone resin.

9. The method for manufacturing an LED device according to claim 7, wherein:
the device has a plurality of the LED chips each having a light source color within a wavelength range from ultra violet rays to infrared rays; and
the plurality of LED chips are composed of LED chips having the same light source color or a combination of LED chips having different light source colors.

10. The method for manufacturing an LED device according to claim 8, wherein:
the device has a plurality of the LED chips each having a light source color within a wavelength range from ultra violet rays to infrared rays; and
the plurality of LED chips are composed of LED chips having the same light source color or a combination of LED chips having different light source colors.

11. The method for manufacturing an LED device according to claim 7, wherein the stem is made of a material exhibiting good heat dissipation effect.

12. The method for manufacturing an LED device according to claim 7, wherein the stem is made of a metal material.

13. The method for manufacturing an LED device according to claim 7, wherein the leads extend from the stem.

14. The method for manufacturing an LED device according to claim 7, wherein locating the at least one LED chip includes mounting the at least one LED chip on the stem.

15. The method for manufacturing an LED device according to claim 7, wherein the first resin has a hardness of from 25 to 40 as measured by JIS A type test (JIS K 6301) and a Young's modulus of less than 0.001 GPa.

16. The method for manufacturing an LED device according to claim 7, wherein the encapsulating resin has a hardness of from 10 to 100 as measured by JIS A type test (JIS K 6301).

17. The LED device according to claim 1, wherein the leads extend from the stem.

18. The LED device according to claim 1, wherein the at least one LED chip is mounted on the stem.

19. The LED device according to claim 1, wherein the first resin has a hardness of from 25 to 40 as measured by JIS A type test (JIS K 6301) and a Young's modulus of less than 0.001 GPa.

20. The LED device according to claim 1, wherein the encapsulating resin has a hardness of from 10 to 100 as measured by JIS A type test (JIS K 6301).
